(19) United States
(12) Patent Application Publication
(10) Pub. No.: US 2026/0366158 A1
(43) Pub. Date: Nov. 19, 2026

(54) MANIFOLD STRUCTURE AND A REACTOR USING THE SAME

(71) Applicant: ASM IP Holding B.V., Almere (NL)

(72) Inventors: Vivek Upadhaya, Hwaseong (KR); DaeYoun Kim, Seo-gu (KR); Yonjong Jeon, Yongin-si (KR); JongHa Yu, Suwon-si (KR); Pilla Anand Raju, Chandler, AZ (US); Jun Yoshikawa, Tokyo (JP); Gaurav Pathak, Chandler, AZ (US)

(21) Appl. No.: 19/654,819

(22) Filed: Apr. 22, 2026

Related U.S. Application Data
(60) Provisional application No. 63/794,575, filed on Apr. 25, 2025.

(51) Int. Cl. C23C 16/455; C23C 16/44; H01J 37/32

(52) U.S. Cl. CPC C23C 16/45565; C23C 16/4402; C23C 16/45536; H01J 37/32357; H01J 37/32449; H01J 2237/3321

(57) ABSTRACT

A manifold for a reactor for processing semiconductor substrates is disclosed to allow for improved gas mixing and reduction of damaging ions. The manifold comprises: a manifold body configured to receive a gas from a plasma unit; a reactant gas inlet tube configured to flow a reactant gas into the manifold body; a top flow control ring (FCR) disposed inside of a top portion of the manifold body, the top FCR comprising a plurality of top injection holes for efficient mixing of the reactant gas; a source gas inlet tube configured to flow a source gas into the manifold body; a bottom flow control ring (FCR) disposed inside a bottom portion of the manifold body, the bottom FCR comprising a plurality of bottom injection holes for efficient mixing of the source gas; and a middle ion filter disposed between the top FCR and the bottom FCR, wherein the middle ion filter is configured to remove ions from a gas flowing in the manifold body.

### CROSS-REFERENCE TO RELATED APPLICATIONS

This application claims priority to U.S. Provisional Patent Application Ser. No. 63/794,575 filed Apr. 25, 2025 titled MANIFOLD STRUCTURE AND A REACTOR USING THE SAME, the disclosure of which is hereby incorporated by reference in its entirety.

### FIELD OF INVENTION

The present disclosure relates generally to a substrate processing apparatus, more particularly to an inductively coupled plasma (ICP) atomic layer deposition (ALD) reactor having a feed manifold equipped with various ion filters for effective ion trapping.

### BACKGROUND OF THE DISCLOSURE

Conventionally, a reaction chamber employs a manifold for injecting a gas for processing substrates as well as helping mix and distribute the gas into a reaction space.

In substrate processing, ions generated during plasma processing may adversely affect the surface of the substrate and cause damage to films or structures formed on the substrate. Thus, it may be necessary to reduce the amount of ions in the plasma for effective substrate processing. At the same time, for those systems employing a remote plasma unit (RPU), gas distribution may also be important to achieve good film quality as well as the reduction of ions.

Therefore, the present disclosure provides a manifold, which may reducing the ions in the plasma gas, while allowing for an even distribution of the gas.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment, a manifold structure for improving reactions in a reactor is disclosed. The manifold comprises: a manifold body configured to receive a gas from a plasma unit; a reactant gas inlet tube configured to flow a reactant gas into the manifold body; a top flow control ring (FCR) disposed inside of a top portion of the manifold body, the top FCR comprising a plurality of top injection holes for efficient mixing of the reactant gas; a source gas inlet tube configured to flow a source gas into the manifold body; a bottom flow control ring (FCR) disposed inside a bottom portion of the manifold body, the bottom FCR comprising a plurality of bottom injection holes for efficient mixing of the source gas; and a middle ion filter disposed between the top FCR and the bottom FCR, wherein the middle ion filter is configured to remove ions from a gas flowing in the manifold body.

In accordance with one embodiment, a reactor for processing semiconductor substrates is disclosed. The reactor comprises: a remote plasma unit (RPU) configured to generate plasma; a manifold disposed between the RPU and a reaction chamber for mixing gases; and a reaction chamber configured to process substrates, wherein the reaction chamber comprises a showerhead, chamber wall and a susceptor for supporting the substrates, and wherein the manifold comprises: a manifold body configured to receive a gas from the RPU; a reactant gas inlet tube configured to flow a reactant gas into the manifold body; a top flow control ring (FCR) disposed inside of a top portion of the manifold body, the top FCR comprising a plurality of top injection holes for efficient mixing of the reactant gas; a source gas inlet tube configured to flow a source gas into the manifold body; a bottom flow control ring (FCR) disposed inside a bottom portion of the manifold body, the bottom FCR comprising a plurality of bottom injection holes for efficient mixing of the source gas; and a middle ion filter disposed between the top FCR and the bottom FCR, wherein the middle ion filter is configured to remove ions from a gas flowing in the manifold body.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overview of a reactor equipped with a manifold structure according to an embodiment of the present disclosure.

FIGS. 2A-2D illustrate close-up views of the manifold structure according to an embodiment of the present disclosure.

FIG. 3A illustrates an ion filter equipped in the manifold according to an embodiment of the present disclosure.

FIG. 3B illustrates a sideview of the ion filter in the manifold according to another embodiment of the present disclosure.

FIG. 3C illustrates a sideview of the ion filter in the manifold according to another embodiment of the present disclosure.

FIG. 4A illustrates a first example of the structure of the ion filters with 2 plates attached to each other according to an embodiment of the present disclosure.

FIG. 4B illustrates a second example of the structure of the ion filters with 2 plates attached to each other according to an embodiment of the present disclosure.

FIG. 4C illustrates a third example of the structure of the ion filters with 2 plates attached to each other according to an embodiment of the present disclosure.

FIG. 5A illustrates a sideview of a flow control ring (FCR) with downwardly inclined holes according to an embodiment of the present disclosure.

FIG. 5B illustrates a sideview of an FCR with flat holes according to an embodiment of the present disclosure.

FIG. 5C illustrates an overview of an FCR according to an embodiment of the present disclosure.

FIG. 6A illustrates an overview of an ion filter with 3 plates spaced with each other according to an embodiment of the present disclosure.

FIG. 6B illustrates overviews of each of the 3 plates according to an embodiment of the present disclosure.

FIG. 7A illustrates a first example of a fourth ion filter disposed below the manifold according to an embodiment of the present disclosure.

FIG. 7B illustrates a second example of an additional ion filter disposed below the manifold according to an embodiment of the present disclosure.

FIG. 7C illustrates an overview of the manifold with an additional ion filter attached below the manifold according to an embodiment of the present disclosure.

FIG. 8A illustrates an overview of a third example of an additional ion filter attached below the manifold according to an embodiment of the present disclosure.

FIG. 8B illustrates an overview of the manifold with an additional ion filter attached below the manifold according to an embodiment of the present disclosure.

FIG. 9A illustrates an overview of a fourth ion filter disposed around the bottom FCR according to an embodiment of the present disclosure.

FIG. 9B illustrates an overview of the flat plate and the holes of a fourth ion filter disposed around the bottom FCR according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

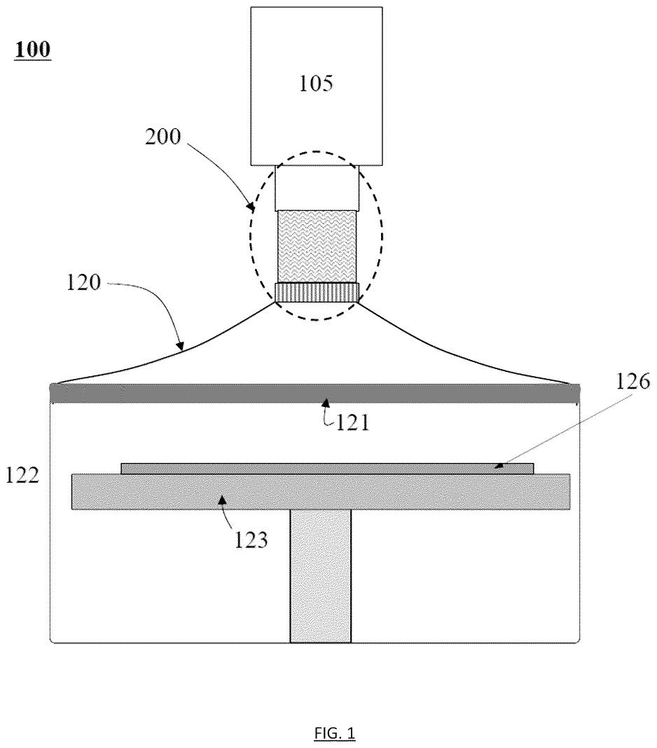

FIG. 1 illustrates an overview of a reactor equipped with a manifold structure according to an embodiment of the present disclosure.

As shown in FIG. 1, the reactor 100 may comprise a remote plasma unit (RPU) 105, a reaction chamber 120, a manifold structure 200 connected to the reaction chamber 120, a showerhead 121, a chamber wall 122, and a susceptor 123. A substrate 126 may be placed on the susceptor 123. The showerhead 121 distributes the gas that flows into the reaction chamber 120 onto the substrate 126. The chamber wall 122 may define boundaries of the reaction chamber 120.

The manifold 200 may be configured to evenly mix a plasma and a gas. The manifold 200 may also be configured to reduce positive ions in the plasma.

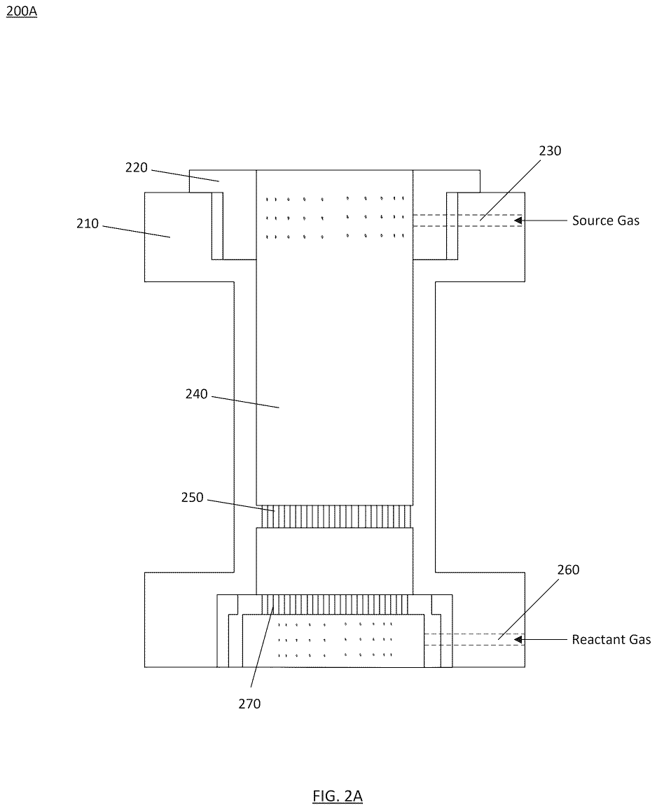

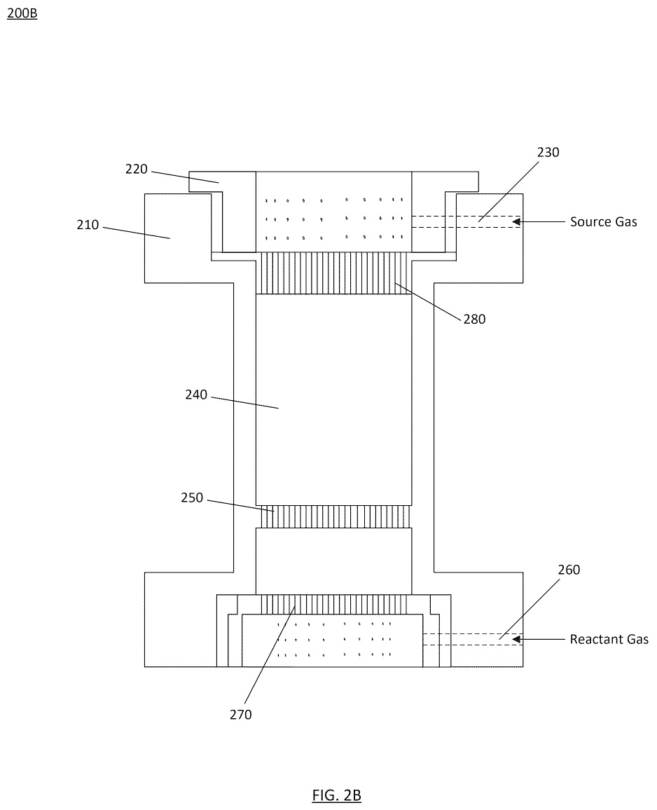

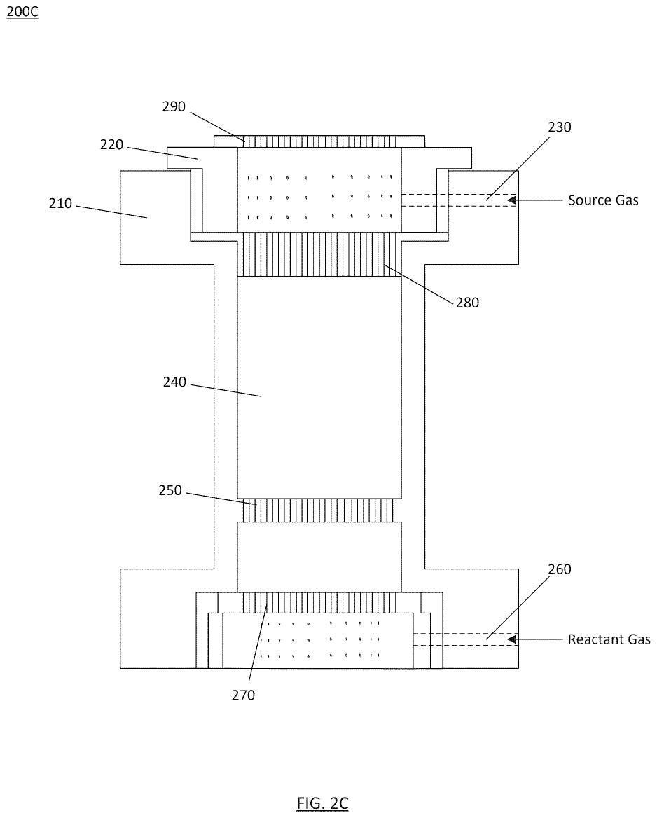

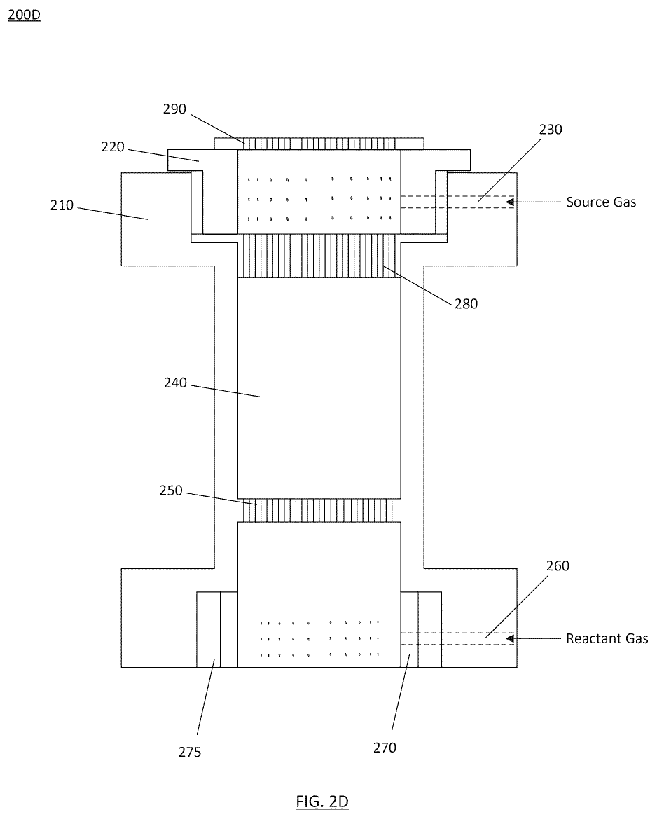

FIG. 2A illustrates a close-up view of a manifold structure 200A according to an embodiment of the present disclosure.

The manifold structure 200A according to the present disclosure comprises a manifold body 210, a top flow control ring (FCR) 220, and a reactant gas inlet tube 230. A reactant gas flows through the reactant gas inlet tube 230 and the top FCR 220 into an interior of the manifold body 210. The top FCR 220 may have a plurality of holes to allow for entry of the reactant gas from a plurality of locations. The reactant gas may comprise a plasma generated gas from the RPU 105 disposed above the manifold structure 200A as well as the reactant gas flowing through the reactant gas inlet tube 230. The plasma generated gas from the RPU 105 may comprise radicals and positive ions, whereby the positive ions may harm the surface of the substrate 126.

The reactant gas then flows into a cavity 240 of the manifold body 210. A mixing of the reactant gas may take place in the cavity 240. The manifold structure 200A may also comprise a middle ion filter 250, a source gas inlet tube 260, and a bottom flow control ring (FCR) 270. The middle ion filter 250 may be configured to remove ions in the gas flowing through the cavity 240 of the manifold body 210. The source gas inlet tube 260 is configured to flow a source gas into the manifold body 210 through the bottom FCR 270.

The bottom FCR 270 may be disposed in a bottom of the manifold body 210 and configured to evenly mix the source gas from the source gas inlet tube 260 prior to the gas entering the reaction chamber 120. The bottom FCR 270 may have a plurality of holes to allow for entry of the reactant gas from a plurality of locations. The bottom FCR 270 optionally may also have an integrated ion filter. The middle ion filter 250 and the bottom FCR 270 may be anodized (e.g., by arc free anodizing) or may comprise ceramic (e.g., alumina, oxidized aluminum, silica coating, or arc free anodized coating) to reduce radical recombination as well as allow for efficient ion entrapment. Radical recombination would reduce the ability of a desired film to be formed on the substrate 126.

FIG. 2B illustrates a close-up view of a manifold structure 200B according to an embodiment of the present disclosure.

The manifold structure 200B according to the present disclosure comprises a manifold body 210, a top flow control ring (FCR) 220, a reactant gas inlet tube 230, and a first upper ion filter 280. A reactant gas flows through the reactant gas inlet tube 230 and the top FCR 220 into an interior of the manifold body 210. The top FCR 220 may have a plurality of holes to allow for entry of the reactant gas from a plurality of locations. The reactant gas may comprise a plasma generated gas from the RPU 105 disposed above the manifold structure 200B as well as the reactant gas flowing through the reactant gas inlet tube 230. The plasma generated gas from the RPU 105 may comprise radicals and positive ions, whereby the positive ions may harm the surface of the substrate 126. The first upper ion filter 280 may be configured to remove ions in the gas flowing through the upper FCR 220.

The reactant gas then flows into a cavity 240 of the manifold body 210. A mixing of the reactant gas may take place in the cavity 240. The manifold structure 200B may also comprise a middle ion filter 250, a source gas inlet tube 260, and a bottom flow control ring (FCR) 270. The middle ion filter 250 may be configured to remove ions flowing through the cavity 240 of the manifold body 210. The middle ion filter 250 is illustrated as being integrated into the manifold body 210, although the middle ion filter 250 may also be configured to be a separate part installed into the manifold body 210. The source gas inlet tube 260 is configured to flow a source gas into the manifold body 210 through the bottom FCR 270.

The bottom FCR 270 may be disposed in a bottom of the manifold body 210 and configured to evenly mix the source gas from the source gas inlet tube 260 prior to the gas entering the reaction chamber 120. The bottom FCR 270 may have a plurality of holes to allow for entry of the reactant gas from a plurality of locations. The bottom FCR 270 optionally may also have an integrated ion filter. The first upper ion filter 280, the middle ion filter 250, and the bottom FCR 270 may be anodized (e.g., by arc free anodizing) or may comprise ceramic (e.g., alumina or oxidized aluminum) to reduce radical recombination as well as allow for efficient ion entrapment. Radical recombination would reduce the ability of a desired film to be formed on the substrate 126.

FIG. 2C illustrates a close-up view of a manifold structure 200C according to an embodiment of the present disclosure.

The manifold structure 200C according to the present disclosure comprises a manifold body 210, a top flow control ring (FCR) 220, a reactant gas inlet tube 230, a first upper ion filter 280, and a second upper ion filter 290. A reactant gas flows through the reactant gas inlet tube 230 and the top FCR 220 into an interior of the manifold body 210. The top FCR 220 may have a plurality of holes to allow for entry of the reactant gas from a plurality of locations. The reactant gas may comprise a plasma generated gas from the RPU 105 disposed above the manifold structure 200C as well as the reactant gas flowing through the reactant gas inlet tube 230. The plasma generated gas from the RPU 105 may comprise radicals and positive ions, whereby the positive ions may harm the surface of the substrate 126. The first upper ion filter 280 may be configured to remove ions in the gas flowing through the upper FCR 220. The second upper ion filter 290 may be configured to remove ions in the gas flowing from the RPU 105.

The reactant gas then flows into a cavity 240 of the manifold body 210. A mixing of the reactant gas may take place in the cavity 240. The manifold structure 200C may also comprise a middle ion filter 250, a source gas inlet tube 260, and a bottom flow control ring (FCR) 270. The middle ion filter 250 may be configured to remove ions flowing through the cavity 240 of the manifold body 210. The middle ion filter 250 is illustrated as being integrated into the manifold body 210, although the middle ion filter 250 may also be configured to be a separate part installed into the manifold body 210. The source gas inlet tube 260 is configured to flow a source gas into the manifold body 210 through the bottom FCR 270.

The bottom FCR 270 may be disposed in a bottom of the manifold body 210 and configured to evenly mix the source gas from the source gas inlet tube 260 prior to the gas entering the reaction chamber 120. The bottom FCR 270 may have a plurality of holes to allow for entry of the reactant gas from a plurality of locations. The bottom FCR 270 optionally may also have an integrated ion filter. The first upper ion filter 280, the second upper ion filter 290, the middle ion filter 250, and the bottom FCR 270 may be anodized (e.g., by arc free anodizing) or may comprise ceramic (e.g., alumina or oxidized aluminum) to reduce radical recombination as well as allow for efficient ion entrapment. Radical recombination would reduce the ability of a desired film to be formed on the substrate 126.

FIG. 2D illustrates a close-up view of a manifold structure 200C according to an embodiment of the present disclosure.

The manifold structure 200D according to the present disclosure comprises a manifold body 210, a top flow control ring (FCR) 220, a reactant gas inlet tube 230, a first upper ion filter 280, and a second upper ion filter 290. A reactant gas flows through the reactant gas inlet tube 230 and the top FCR 220 into an interior of the manifold body 210. The top FCR 220 may have a plurality of holes to allow for entry of the reactant gas from a plurality of locations. The reactant gas may comprise a plasma generated gas from the RPU 105 disposed above the manifold structure 200D as well as the reactant gas flowing through the reactant gas inlet tube 230. The plasma generated gas from the RPU 105 may comprise radicals and positive ions, whereby the positive ions may harm the surface of the substrate 126. The first upper ion filter 280 may be configured to remove ions in the gas flowing through the upper FCR 220. The second upper ion filter 290 may be configured to remove ions in the gas flowing from the RPU 105.

The reactant gas then flows into a cavity 240 of the manifold body 210. A mixing of the reactant gas may take place in the cavity 240. The manifold structure 200C may also comprise a middle ion filter 250, a source gas inlet tube 260, a bottom flow control ring (FCR) 270, and a bottom ion filter 275. The middle ion filter 250 may be configured to remove ions flowing through the cavity 240 of the manifold body 210. The middle ion filter 250 is illustrated as being integrated into the manifold body 210, although the middle ion filter 250 may also be configured to be a separate part installed into the manifold body 210. The source gas inlet tube 260 is configured to flow a source gas into the manifold body 210 through the bottom FCR 270.

The bottom FCR 270 may be disposed in a bottom of the manifold body 210 and configured to evenly mix the source gas from the source gas inlet tube 260 prior to the gas entering the reaction chamber 120. The bottom FCR 270 may have a plurality of holes to allow for entry of the reactant gas from a plurality of locations. The bottom ion filter 275 may be disposed vertically to surround the bottom FCR 270. The first upper ion filter 280, the second upper ion filter 290, the middle ion filter 250, and the bottom ion filter 275 may be anodized (e.g., by arc free anodizing) or may comprise ceramic (e.g., alumina or oxidized aluminum) to reduce radical recombination as well as allow for efficient ion entrapment. Radical recombination would reduce the ability of a desired film to be formed on the substrate 126.

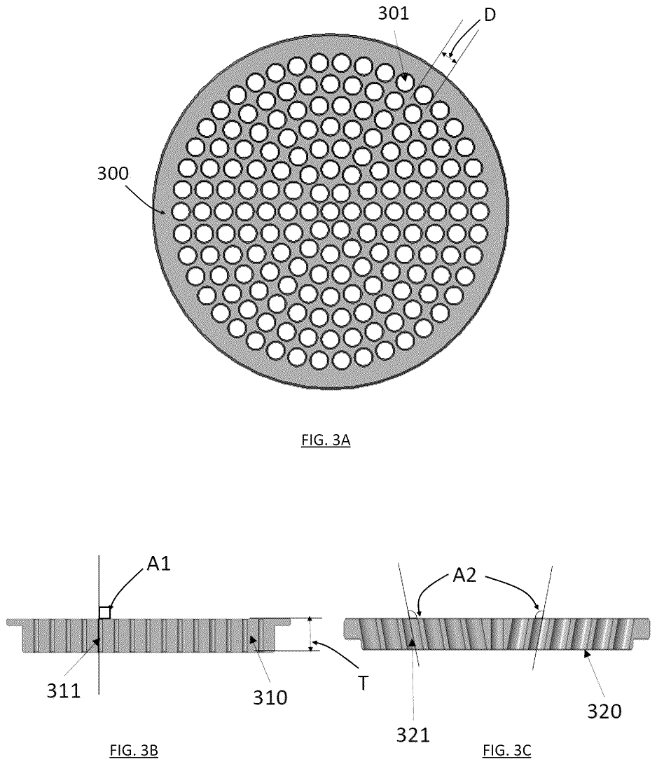

FIG. 3A illustrates an example of an ion filter configured to fit in the manifold body according to an embodiment of the present disclosure.

The shape of the ion filters may be the same or different. However, an ion filter 300 may be shaped like a circle with many holes 301 with a certain diameter D as shown in FIG. 3A. A hole 311 may be formed perpendicularly at a right angle A1 (90 degrees) in FIG. 3B. Or a hole 321 may be slanted at an predetermined angle of A2 degrees as shown in FIG. 3C. The ion filters 300, 310, 320 may have a predetermined thickness T.

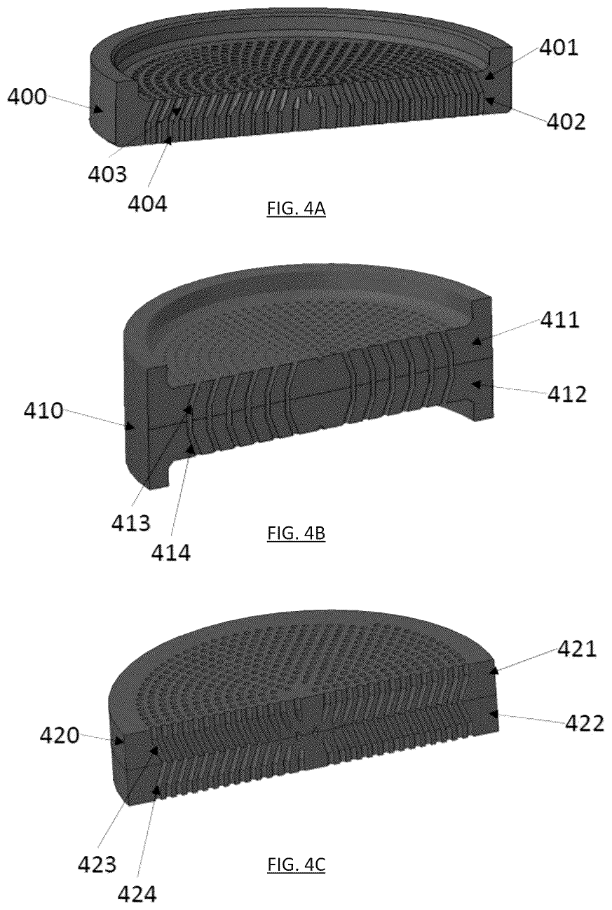

The ion filter may comprise more than one piece. FIG. 4A illustrates a first structure of an ion filter with 2 plates (layers) attached to each other according to an embodiment of the present disclosure. An ion filter 400 may comprise an upper plate 401 and a lower plate 402. A plurality of holes 403 in the upper plate 401 may be inclined while a plurality of holes 404 in the lower plate 402 may be vertical. The holes 403 may align with the holes 404.

A second example of an ion filter 410 is illustrated in FIG. 4B. The ion filter 410 may comprise an upper plate 411 and a lower plate 412. A plurality of holes 413 in the upper plate 411 may be inclined while a plurality of holes 414 in the lower plate 402 may also be inclined. The holes 413 may align with the holes 414.

A third example of the structure of an ion filter 420 is illustrated in FIG. 4C. The ion filter 420 may comprise an upper plate 421 and a lower plate 422. A plurality of holes 423 in the upper plate 421 may be partly vertical and partly inclined. A plurality of holes 424 in the lower plate 422 may also be partly vertical and partly inclined. The holes 423 may align with the holes 424.

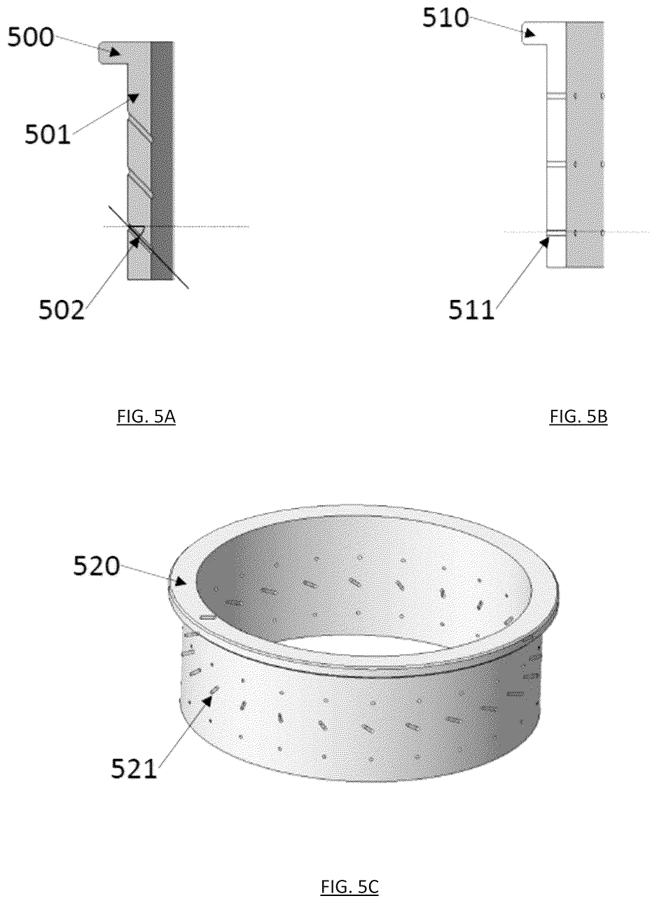

FIGS. 5A-5C illustrate a sideview of a flow control ring (FCR) with downwardly inclined holes and horizontal holes respectively according to an embodiment of the present disclosure.

A FCR 500 may be equipped with a FCR wall 501 and a plurality of holes 502 for injecting a gas from gas source for substrate processing. The direction of the hole may vary to improve the mixture and distribution of the gas. In FIG. 5A, the holes 502 may be inclined downward while a plurality of holes 511 in FIG. 5B may be horizontal and flat. The overall view of a FCR 520 with a plurality of holes 521 is illustrated in FIG. 5C.

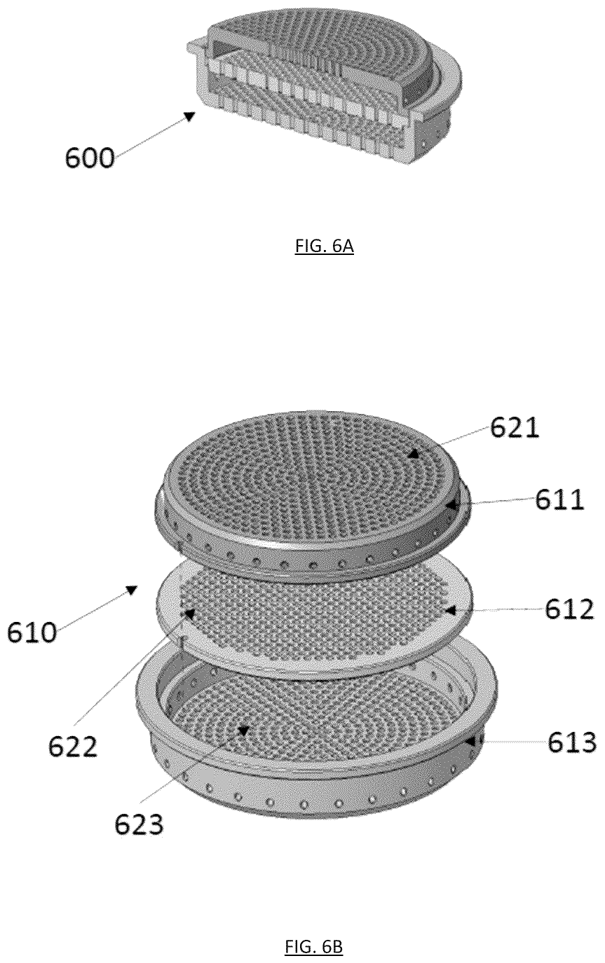

FIGS. 6A and 6B illustrate overviews of each of the 3 plates according to an embodiment of the present disclosure.

The ion filter according to another embodiment of the present disclosure may comprise more than two plates (layers). For example, an ion filter 610 may comprise a first plate 611, a second plate 612, and a third plate 613. Each of the plates 611, 612, 613 may have a plurality of holes 621, 622, 623 respectively but the holes may or may not be aligned vertically. The alignment may be decided by environmental parameters and other issues.

Therefore, the ion filter 600 in FIG. 6A may be employed as employed as any one of the first upper ion filter 280, the second upper ion filter 290, the middle ion filter 250, the bottom FCR 270, or the bottom ion filter 275 as illustrated in FIGS. 2A-2D. The ion filters 600-610 may be anodized (e.g., by arc free anodizing) or may comprise ceramic (e.g., alumina or oxidized aluminum) to reduce radical recombination as well as allow for efficient ion entrapment.

In inductively coupled plasma (ICP) ALD processes, ion elimination (by filtering and entrapment) is important since the ions have negative impact on the substrate uniformity, gap fill result, oxidation and ion-induced damage on the substrates. Therefore, ion reduction and/or elimination in the plasma flow is important in many ways.

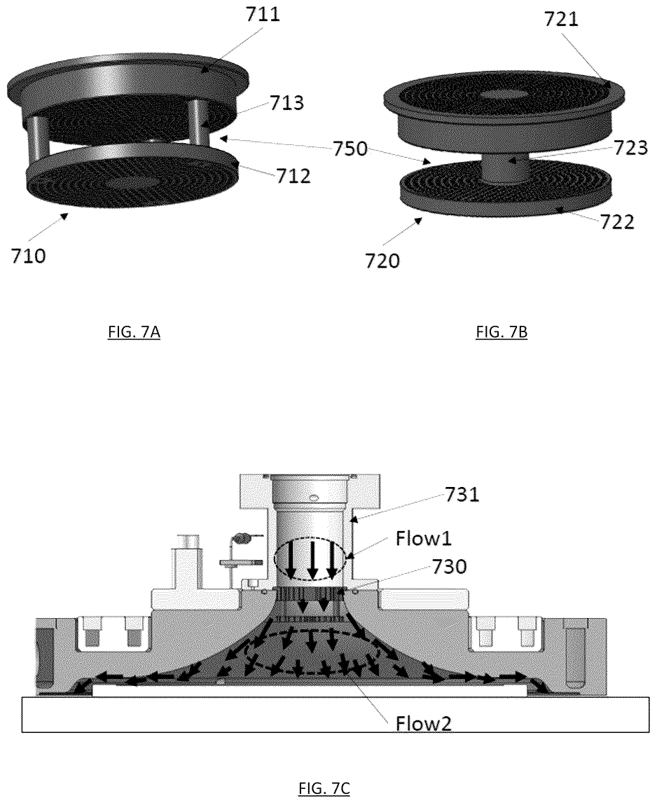

For efficient ion elimination and/or elimination, the present disclosure presents another ion filter attached at below the manifold structure. FIG. 7A illustrates a first example of an additional ion filter disposed below the manifold according to an embodiment of the present disclosure.

The additional ion filter may reduce the ion in the plasma flow as well as help distribute the plasma flow uniformly over the substrate. For this purpose, an additional ion filter may comprise a first layer and a second layer and a connecting element configured to connect the first layer and the second layer. For smooth mixture and distribution of the plasma flow, the first and second layers are spaced with the distance of the connecting material.

The connecting material may be shaped in many ways, but the present disclosure presents two distinctive modes. One is illustrated in FIG. 7A. In this, a connecting element 713 may connect a first layer 711 and a second later 712 and the connecting element may have at least 2 connections (3 connections in FIG. 7A) in a rim area of the first and the second layers. The other is illustrated in FIG. 7B and a connecting element 723 may connect a first layer 721 and a second layer 722 with a single connection in the center area of the first and second layers 721, 722.

With a space 750 between the first layer 711, 721 and the second layer 712, 722, the plasma flow from a remote plasma unit coming through a manifold 731 (“Flow1”) may have more swirling and random flow and will be mixed and distributed efficiently over the substrate in a chamber (“Flow2”). FIG. 7C illustrates an overview of the manifold 731 with an additional ion filter 730 attached below the manifold according to an embodiment of the present disclosure.

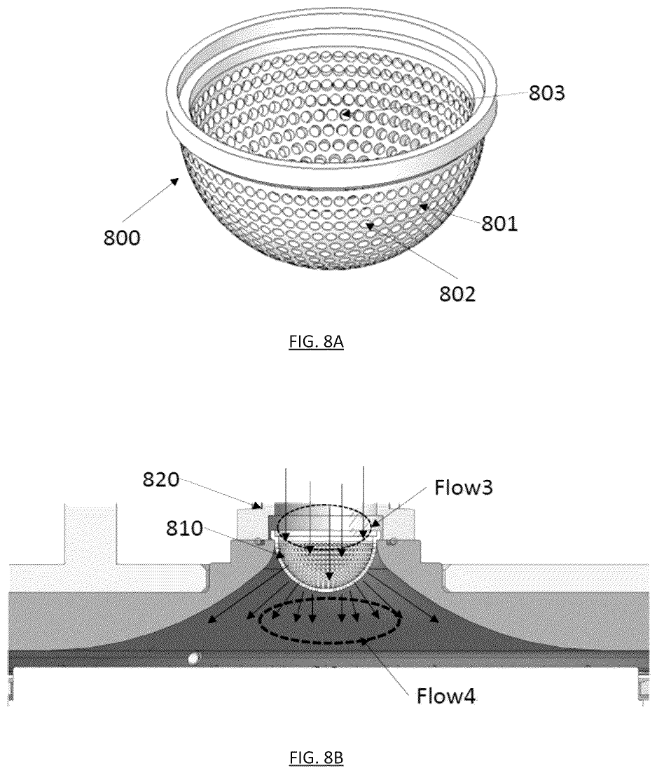

The additional ion filter may have another shape. In FIGS. 8A and 8B, another shape embodiment of the additional ion filter and its attachment to the manifold may be illustrated respectively.

An additional ion filter 800 may comprise a hemisphere sieve 802 with a plurality of holes 801 in it. With this shape, the ion filter 800 may have a space 803 when attached to bottom of a manifold 820 so that the plasma flow from the manifold 820 (“Flow3”) may be effectively mixed and distributed over the substrate (“Flow4”). The ion filter 800 may be anodized (e.g., by arc free anodizing) or may comprise ceramic (e.g., alumina or oxidized aluminum) to reduce radical recombination as well as allow for efficient ion entrapment.

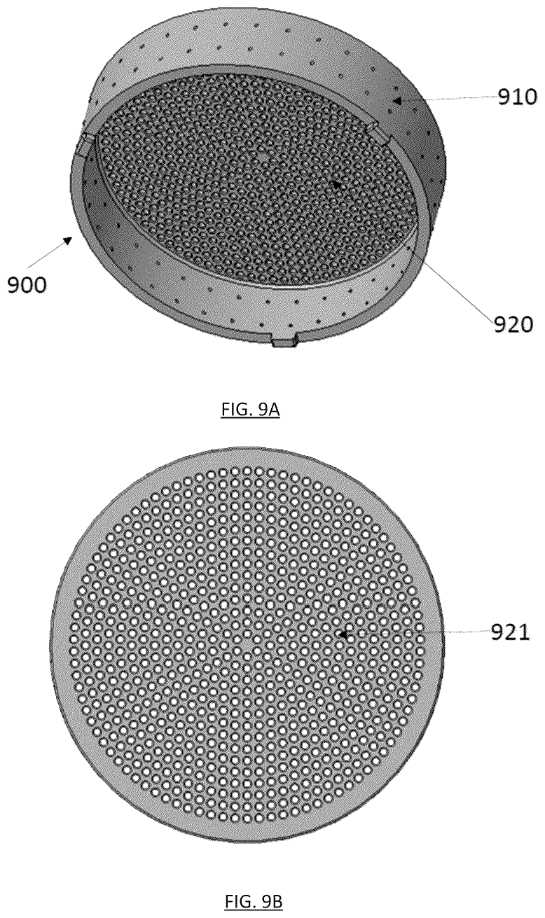

FIGS. 9A and 9B illustrate an overview of a bottom FCR with an integrated ion filter according to an embodiment of the present disclosure respectively.

A fourth ion filter 900 may comprise a side wall 910 and a flat plate 920 configured to surround the bottom FCR as shown in FIG. 5C. The side wall 910 and the flat plate 920 may comprise a plurality of holes 921 in it. The fourth ion filter 900 may be anodized (e.g., by arc free anodizing) or may comprise ceramic (e.g., alumina or oxidized aluminum) to reduce radical recombination as well as allow for efficient ion entrapment.

The ion filters (first, second, third, fourth, additional) may or may not be integrated to the manifold cylinder as a one-body part for better heat dissipation.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A manifold structure configured for mixing gases flowed in a reactor, comprising:
a manifold body configured to receive a gas from a plasma unit;
a reactant gas inlet tube configured to flow a reactant gas into the manifold body;
a top flow control ring (FCR) disposed inside of a top portion of the manifold body, the top FCR comprising a plurality of top injection holes for efficient mixing of the reactant gas;
a source gas inlet tube configured to flow a source gas into the manifold body;
a bottom flow control ring (FCR) disposed inside a bottom portion of the manifold body, the bottom FCR comprising a plurality of bottom injection holes for efficient mixing of the source gas; and
a middle ion filter disposed between the top FCR and the bottom FCR, wherein the middle ion filter is configured to remove ions from a gas flowing in the manifold body.

2. The manifold structure according to claim 1, wherein the middle ion filter is anodized.

3. The manifold structure according to claim 1, wherein the middle ion filter comprises a ceramic comprising at least one of: alumina, oxidized aluminum, silica, or arc free oxidized coating.

4. The manifold structure according to claim 1, further comprising an ion filter integrated into the bottom FCR, wherein the integrated ion filter is configured to remove ions from a gas flowing in the manifold body.

5. The manifold structure according to claim 1, further comprising an ion filter vertically surrounding the bottom FCR, wherein the surrounding ion filter is configured to remove ions from a gas flowing in the manifold body.

6. The manifold structure according to claim 1, further comprising a first upper ion filter disposed directly below the top FCR, wherein the first upper ion filter is configured to remove ions from a gas flowing in the manifold body.

7. The manifold structure according to claim 6, wherein the first upper ion filter comprises a first layer, a second layer, and a connecting element disposed between the first layer and the second layer and configured to connect the first layer and the second layer.

8. The manifold structure according to claim 6, wherein the first upper ion filter comprises a first piece bonded to a second piece, the first piece and the second piece each comprising a plurality of holes.

9. The manifold structure according to the claim 1, further comprising a second upper ion filter disposed directly above the top FCR, wherein the second upper ion filter is configured to remove ions from a gas flowing in the manifold body.

10. The manifold structure according to the claim 9, wherein the second upper ion filter comprises a hemispherical sieve with a plurality of holes.

11. The manifold structure according to the claim 1, wherein the injection holes of the top FCR and the injection holes of the bottom FCR are inclined downward at a predetermined angle.

12. A reactor used for processing substrates, comprises:
a remote plasma unit (RPU) configured to generate plasma;
a manifold disposed between the RPU and a reaction chamber for mixing gases; and
a reaction chamber configured to process substrates, wherein the reaction chamber comprises a showerhead, chamber wall and a susceptor for supporting the substrates, and
wherein the manifold comprises:
a manifold body configured to receive a gas from the RPU;
a reactant gas inlet tube configured to flow a reactant gas into the manifold body;
a top flow control ring (FCR) disposed inside of a top portion of the manifold body, the top FCR comprising a plurality of top injection holes for efficient mixing of the reactant gas;
a source gas inlet tube configured to flow a source gas into the manifold body;
a bottom flow control ring (FCR) disposed inside a bottom portion of the manifold body, the bottom FCR comprising a plurality of bottom injection holes for efficient mixing of the source gas; and
a middle ion filter disposed between the top FCR and the bottom FCR, wherein the middle ion filter is configured to remove ions from a gas flowing in the manifold body.

13. The reactor according to claim 12, wherein the middle ion filter is anodized.

14. The reactor according to claim 12, wherein the middle ion filter comprises a ceramic comprising at least one of: alumina, oxidized aluminum, silica, or arc free oxidized coating.

15. The reactor according to claim 12, further comprising an ion filter integrated into the bottom FCR, wherein the integrated ion filter is configured to remove ions from a gas flowing in the manifold body.

16. The reactor according to claim 12, further comprising an ion filter vertically surrounding the bottom FCR, wherein the surrounding ion filter is configured to remove ions from a gas flowing in the manifold body.

17. The reactor according to claim 12, further comprising a first upper ion filter disposed directly below the top FCR, wherein the first upper ion filter is configured to remove ions from a gas flowing in the manifold body.

18. The reactor according to claim 17, wherein the first upper ion filter comprises a first layer, a second layer, and a connecting element disposed between the first layer and the second layer and configured to connect the first layer and the second layer.

19. The reactor according to claim 17, wherein the first upper ion filter comprises a first piece bonded to a second piece, the first piece and the second piece each comprising a plurality of holes.

20. The reactor according to claim 12, further comprising a second upper ion filter disposed directly above the top FCR, wherein the second upper ion filter is configured to remove ions from a gas flowing in the manifold body.
